(19) United States
(12) Patent Application Publication
(10) Pub. No.: US 2006/0220246 A1
(43) Pub. Date: Oct. 5, 2006

(54) Bump land structure of circuit substrate for semiconductor package

(76) Inventors: Kil-Soo Kim, Asan-si (KR); In-Sook Jung, Suwon-si (KR)

Correspondence Address: HARNESS, DICKEY & PIERCE, P.L.C., P.O. BOX 8910, RESTON, VA, 20195, US

(21) Appl. No.: 11/294,349

(22) Filed: Dec. 6, 2005

(30) Foreign Application Priority Data
Dec. 7, 2004 (KR) 10-2004-0102367

(51) Int. Cl. H01L 23/48

(52) U.S. Cl. 257/738

(57) ABSTRACT

A bump land structure of a circuit substrate for a semiconductor package may have a combination of an SMD type bump land structure and an NSMD type bump land structure. A lower portion of a solder mask and a lower layer of a bump land may form the SMD type bump land structure. An upper portion of a solder mask and an upper layer of a bump land may form the NSMD type bump land structure.

### PRIORITY STATEMENT

This U.S. non-provisional application claims priority under 35 U.S.C. § 119 from Korean Patent Application No. 2004-102367, filed on Dec. 7, 2004, the entire contents of which are incorporated herein by reference.

### BACKGROUND OF THE INVENTION

1. Field of the Invention

The present invention relates generally to circuit substrates for semiconductor packages and, more particularly, to bump land structures of circuit substrates.

2. Description of the Related Art

Integration technology for integrated circuits (ICs) may make it possible to connect many circuits in and on a semiconductor chip at a given chip size. Thus, a package, which contains the semiconductor chip therein, may have many input/output (I/O) terminals communicating with external circuitry such as a motherboard, for example.

A ball grid array (BGA) package may have I/O terminals distributed over a package surface, rather than just located peripherally at one or more package edges (as in a conventional lead frame package, for example). A BGA package may have a circuit substrate for the I/O terminals. The circuit substrate may be in the form of a printed circuit board (PCB), for example.

Throughout this disclosure, the terms “upper,” “lower,” “top,” and “bottom” are used for convenience in describing various elements or portions or regions of the elements as shown in the figures. These terms do not, however, require that the structure be maintained in any particular orientation.

FIG. 1 is a cross-sectional view of a conventional semiconductor package 10 that may include a circuit substrate 11. The circuit substrate 11 may have an upper surface 11a and a lower surface 11b. The circuit substrate 11 may have a circuit track (not shown) formed on the upper surface 11a. An integrated circuit (IC) chip 12 may be mounted on the upper surface 11a of the circuit substrate 11. Bonding wires 13 may electrically connect the IC chip 12 to the circuit track. An encapsulant 14 may be formed on the upper surface 11a of the circuit substrate 11 to protect the IC chip 12 and the bonding wires 13 from the external environment.

A plurality of solder bumps 15 may be formed on the lower surface 11b of the circuit substrate 11. The solder bumps 15 may have a spherical or ball shape as shown in FIG. 1. Of course the solder bumps 15 may have other, alternative shapes. The solder bumps 15 may be arranged on the lower surface 11b of the circuit substrate 11 in a pattern, for example in a grid fashion. Vias (not shown) may be formed in the circuit substrate 11 and electrically connect the solder bumps 15 to the circuit tracks on the upper surface 11a of the circuit substrate 11.

The lower surface 11b of the circuit substrate 11 may include a solder bump-forming area that may support a bump land. There are a variety of conventional bump land structures, inclusive of a solder mask defined (SMD) type and a non-solder mask defined (NSMD) type.

FIG. 2 is a plan view of a conventional SMD type bump land structure 20a. FIG. 3 is a cross-sectional view taken along the line of III-III of FIG. 2.

Referring to FIGS. 2 and 3, a circuit substrate may include a substrate core 21 that may support a bump land 22 and a circuit track 23. A solder mask 24 may be provided on the substrate core 21. The solder mask 24 may cover a peripheral portion of the bump land 22 and the circuit track 23. The solder mask 24 may define a window 24a. The window 24a may expose a portion of the bump land 22.

FIG. 4 is a plan view of a conventional NSMD type bump land structure 20b. FIG. 5 is a cross-sectional view taken along the line of V-V of FIG. 4.

Referring to FIGS. 4 and 5, a circuit substrate may include a substrate core 21 that may support a bump land 22 and a circuit track 23. A solder mask 24 may be provided on the substrate core 21. The solder mask 24 may cover the circuit track 23. The solder mask 24 may define a window 24a. The window 24a may expose the bump land 22. A portion 23a of the circuit track 23 connected to the bump land 22, and a portion 21a of the surface of the substrate core 21 may be exposed through the window 24a. The conventional NSMD type bump land structure may have the bump land 22 spaced apart from the solder mask 24.

The conventional SMD type bump land structure 20a and the conventional NSMD type bump land structure 20b, as described above, may each have associated advantages and disadvantages.

For example, the SMD type bump land structure 20a may be relatively strong against external stresses because the peripheral portion of the bump land 22 may be covered with the solder mask 24. On the other hand, the solder bump (e.g., 15 of FIG. 1) may be provided on the bump land 22. Here, a portion of the solder bump may enter into the window 24a of the solder mask 24 and have a neck shape. The neck shape may reduce bump joint reliability.

A neck shape may not appear in the NSMD type bump land structure 20b and the NSMD type bump land structure 20b may be relatively strong against internal stresses because the bump land 22 may be exposed through the window 24a. However, cracks may occur at the exposed portion 23a of the circuit track 23. If the orientation of stress is along the direction of the circuit track 23, bump joint reliability may be reduced. Further, the adhesive strength between the bump land 22 and the substrate core 21 may be reduced, thereby resulting in delamination.

### SUMMARY OF THE INVENTION

According to an example, non-limiting embodiment of the present invention, a circuit substrate may include a substrate core. A bump land may be provided on the substrate core. A solder mask may be provided on the substrate core. The bump land may include a lower layer provided on the substrate core and an upper layer provided on the lower layer. The solder mask may include a lower portion provided on the substrate core, and an upper portion provided on the lower portion. The lower portion may cover a top peripheral region of the lower layer of the bump land. The upper portion may expose a top face of the upper layer of the bump land.

According to another example, non-limiting embodiment of the present invention, a circuit substrate may include a substrate core. A bump land may be provided on the substrate core. A solder mask may be provided on the substrate core. The bump land may include a lower layer provided on the substrate core, an intermediate layer provided on the lower layer, and an upper layer provided on the intermediate layer. The solder mask may include a lower portion provided on the substrate core, and an upper portion provided on the lower portion. The lower portion may cover a top peripheral region of the lower layer of the bump land and may surround a side face of the intermediate layer of the bump land. The upper portion may expose a top face and a side face of the upper layer of the bump land.

According to another example, non-limiting embodiment of the invention, a bump land structure may include a bump land. The bump land may have a lower layer having a major surface with a mounting region and a peripheral region contiguous with and surrounding the mounting region. The bump land may also include an upper layer provided on the mounting region of the major surface of the lower layer. A solder mask may cover the entire peripheral region of the major surface of the lower layer of the bump land.

According to another example, non-limiting embodiment of the invention, a method of manufacturing a bump land structure may involve providing a bump land lower layer having a major surface with a mounting region and a peripheral region contiguous with and surrounding the mounting region. A bump land upper layer may be provided on the mounting region of the major surface of the bump land lower layer. A solder mask may be provided to cover the entire peripheral region of the major surface of the bump land lower layer.

### BRIEF DESCRIPTION OF THE DRAWINGS

Example, non-limiting embodiments of the present invention will be readily understood with reference to the following detailed description thereof provided in conjunction with the accompanying drawings.

FIG. 1 is a cross-sectional view of a conventional semiconductor package having a circuit substrate.

FIG. 2 is a plan view of a conventional SMD type bump land structure.

FIG. 3 is a cross-sectional view taken along the line of III-III of FIG. 2.

FIG. 4 is a plan view of a conventional NSMD type bump land structure.

FIG. 5 is a cross-sectional view taken along the line of V-V of FIG. 4.

FIG. 6 is a plan view of a bump land structure of a circuit substrate in accordance with an example, non-limiting embodiment of the present invention.

FIG. 7 is a cross-sectional view taken along the line of VII-VII of FIG. 6.

FIG. 8 is a plan view of a bump land structure of a circuit substrate in accordance with another example, non-limiting embodiment of the present invention.

FIG. 9 is a cross-sectional view taken along the line of IX-IX of FIG. 8.

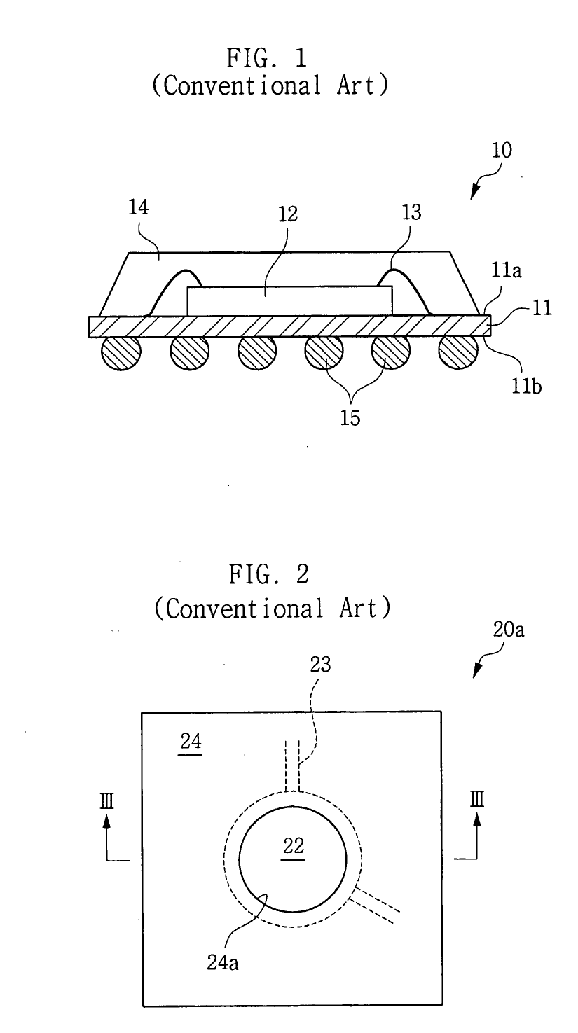

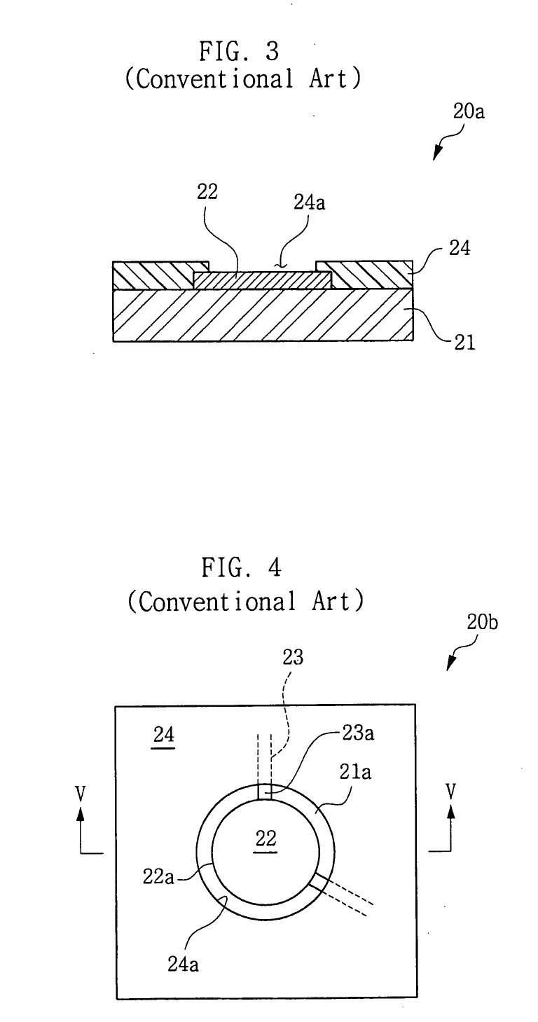

The drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the invention.

### DETAILED DESCRIPTION OF EXAMPLE EMBODIMENTS OF THE INVENTION

Example, non-limiting embodiments of the present invention will now be described more fully hereinafter with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and feature of this invention may be employed in varied and numerous embodiments without departing from the scope of the invention.

Well-known structures and processes are not described or illustrated in detail to avoid obscuring embodiments of the present invention.

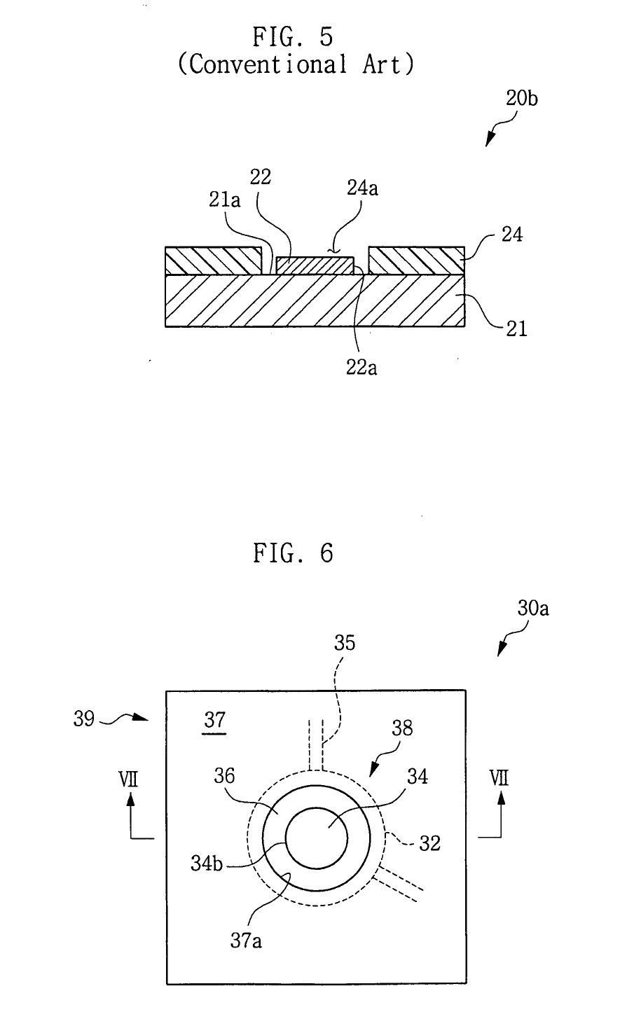

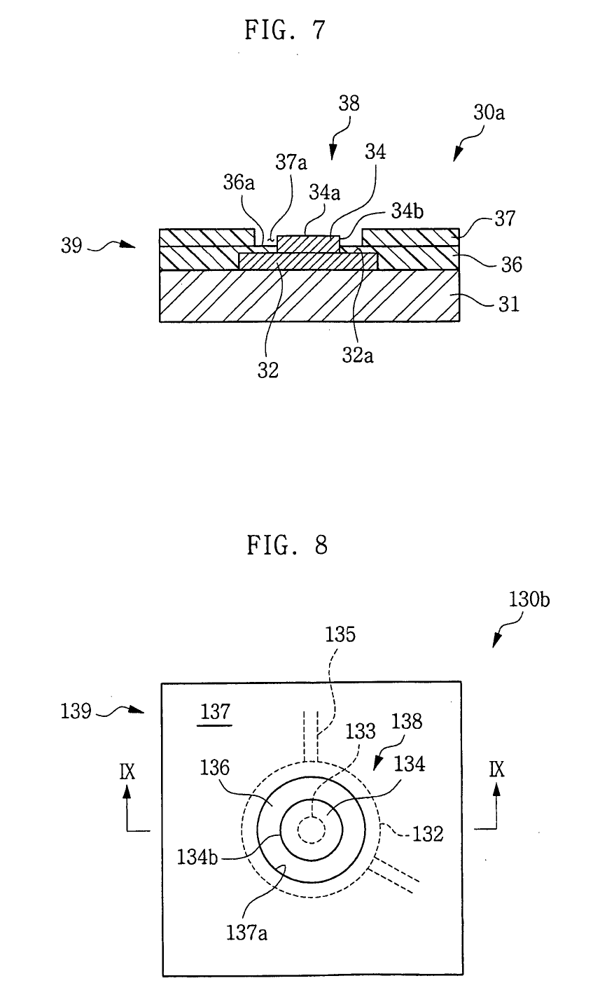

FIG. 6 is a plan view of a bump land structure 30a of a circuit substrate in accordance with an example, non-limiting embodiment of the present invention. FIG. 7 is a cross-sectional view taken along the line of VII-VII of FIG. 6. Although FIGS. 6 and 7 show a single bump land structure 30a, a plurality of the bump land structures 30a may be distributed over the lower surface of the circuit substrate.

Referring to FIGS. 6 and 7, the circuit substrate may include a substrate core 31. An upper surface of the substrate core 31 may include a solder bump-forming area that may support a bump land 38. The upper surface of the substrate core 31 may also support a circuit track 35. A solder mask 39 may cover a portion of the substrate core 31 and the circuit track 35. The bump land 38 and the circuit track 35 may be formed of conductive materials, which are well known in this art. The substrate core 31 and the solder mask 39 may be formed of non-conductive materials, which are well known in this art.

The bump land 38 may include a lower layer 32 and an upper layer 34. The lower layer 32 of the bump land 38 may be provided on the solder bump-forming area of the substrate core 31. By way of example only, the lower layer 32 may have a circular shape. In alternative embodiments, however, the lower layer 32 may have any other geometrical shape. The upper layer 34 of the bump land 38 may be provided on the lower layer 32 of the bump land 38. By way of example only, the upper layer 34 may have a circular shape. In alternative embodiments, however, the upper layer 34 may have any other geometrical shape. The diameter of the upper layer 34 may be smaller than that of the lower layer 32. The upper layer 34 may be positioned on the lower layer 32 so that a top peripheral region 32a of the lower layer 32 may be exposed. The circuit track 35 may be connected to the lower layer 32 of the bump land 38.

The solder mask 39 may include a lower portion 36 and an upper portion 37. The lower portion 36 of the solder mask 39 may be provided on the substrate core 31. The upper portion 37 of the solder mask 39 may be provided on the lower portion 36 of the solder mask 39. The thickness of the lower portion 36 of the solder mask 39 may be greater than that of the lower layer 32 of the bump land 38. The lower portion 36 of the solder mask 39 may extend onto and cover the top peripheral region 32a of the lower layer 32 of the bump land 38. In this regard, the lower portion 36 of the solder mask 39 and the lower layer 32 of the bump land 38 may form an SMD type bump land structure.

The lower portion 36 of the solder mask 39 may surround a side face 34b of the upper layer 34 of the bump land 38. A top face 34a of the upper layer 34 may be positioned higher than a top face 36a of the lower portion 36. The top face 34a of the upper layer 34 of the bump land 38 may be exposed through the lower portion 36 of the solder mask 39.

The upper portion 37 of the solder mask 39 may include a window 37a exposing the upper layer 34 of the bump land 38. By way of example only, the window 37a may have a circular shape. In alternative embodiments, however, the window 37a may have any other geometrical shape. The diameter of the window 37a may be larger than that of the upper layer 34 of the bump land 38. The side face of the window 37a may be spaced apart from the side face 34b of the upper layer 34 of the bump land 38. In this regard, the upper portion 37 of the solder mask 39 and the upper layer 34 of the bump land 38 may form an NSMD type bump land structure.

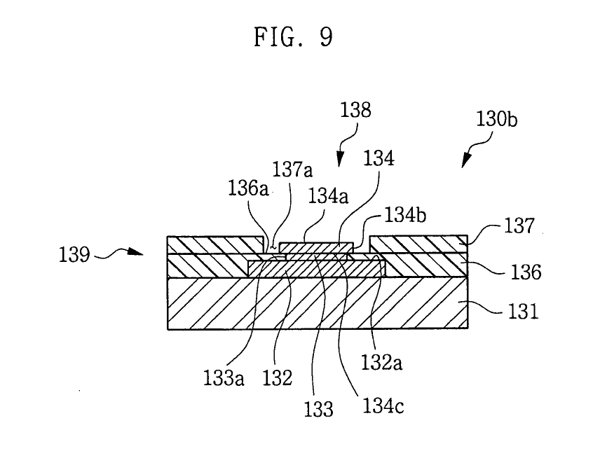

FIG. 8 is a plan view of a bump land structure 130b of a circuit substrate in accordance with another example, non-limiting embodiment of the present invention. FIG. 9 is a cross-sectional view taken along the line of IX-IX of FIG. 8.

Referring to FIGS. 8 and 9, the circuit substrate may include a substrate core 131. An upper surface of the substrate core 131 may include a solder bump-forming area that may support a bump land 138. The upper surface of the substrate core 131 may also support a circuit track 135. A solder mask 139 may cover a portion of the substrate core 131 and the circuit track 135. The bump land 138 and the circuit track 135 may be formed of conductive materials, which are well known in this art. The substrate core 131 and the solder mask 139 may be formed of non-conductive materials, which are well known in this art.

The bump land 138 may include a lower layer 132, an intermediate layer 133, and an upper layer 134. The lower layer 132 may be provided on the bump-forming area of the substrate core 131. By way of example only, the lower layer 132 may have a circular shape. In alternative embodiments, however, the lower layer 132 may have any other geometrical shape. The intermediate layer 133 may be provided on the lower layer 132. By way of example only, the intermediate layer 133 may have a circular shape. In alternative embodiments, however, the intermediate layer 133 may any other geometrical shape. The upper layer 134 may be provided on the intermediate layer 133. By way of example only, the upper layer 134 may have a circular shape. In alternative embodiments, however, the upper layer 134 may have any other geometric shape. The diameter of the upper layer 134 may be smaller than that of the lower layer 132. The diameter of the intermediate layer 133 may be smaller than that of the upper layer 134. The layers 132, 133 and 134 may be arranged so that a top peripheral region 132a of the lower layer 132 may be exposed. The circuit track 135 may be connected to the lower layer 132 of the bump land 138.

The solder mask 139 may include a lower portion 136 and an upper portion 137. The lower portion 136 of the solder mask 139 may be provided on the substrate core 131. The upper portion 137 of the solder mask 139 may be provided on the lower portion 136 of the solder mask 139. The thickness of the lower portion 136 of the solder mask 139 may be greater than that of the lower layer 132 of the bump land 138. The lower portion 136 of the solder mask 139 may extend onto and cover the top peripheral region 132a of the lower layer 132 of the bump land 138. In this regard, the lower portion 136 of the solder mask 139 and the lower layer 132 of the bump land 138 may form an SMD type bump land structure.

The area of the upper layer 134 of the bump land 138 (in plan view) may be larger than that of the intermediate layer 133 of the bump land 138. A bottom face 134c of the upper layer 134 of the bump land 138 may be positioned at the same level as a top face 136a of the lower portion 136 of the solder mask 139. The top face 134a and a side face 134b of the upper layer 134 of the bump land 138 may be exposed through the lower portion 136 of the solder mask 139. The lower portion 136 of the solder mask 139 may extend into a space between the lower layer 132 and the upper layer 134 of the bump land 138 to surround the side face 133a of the intermediate layer 133 of the bump land 138.

The upper portion 137 of the solder mask 139 may include a window 137a exposing the top face 134a and side face 134b of the upper layer 134 of the bump land 138. By way of example only, the window 137a may have a circular shape. In alternative embodiments, however, the window 137a may have any other geometric shape. The diameter of the window 137a may be larger than that of the upper layer 134 of the bump land 138. The side face of the window 137a may be spaced apart from the side face 134b of the upper layer 134 of the bump land 138. In this regard, the upper portion 137 of the solder mask 139 and the upper layer 134 of the bump land 138 may form an NSMD type bump land structure.

In accordance with the example, non-limiting embodiments of the present invention, a bump land structure of a circuit substrate may have a combination of an SMD type bump land structure and an NSMD type bump land structure. For example, a lower portion of a solder mask and a lower layer of a bump land may form an SMD type bump land structure. Cracking of a circuit track and/or delamination of the bump land may be reduced. An intermediate layer may be interposed between the lower layer and an upper layer of the bump land. The intermediate layer may have a side face that may be surrounded by a lower portion of the solder mask.

The upper portion of the solder mask and the upper layer of the bump land may form an NSMD type bump land structure. Therefore, bump joint reliability may be improved.

A circuit substrate having such a bump land structure may be advantageous in a semiconductor package using solder bumps as external connection terminals, such as a BGA package, for example.

While this invention has been particularly shown and described with reference to example, non-limiting embodiments thereof, it will be understood by those skilled in the art that various changes in form and details may be made therein without departing from the spirit and scope of the invention as defined by the appended claims.

What is claimed is:

1. A circuit substrate comprising:
a substrate core;
a bump land provided on the substrate core, the bump land including a lower layer provided on the substrate core, and an upper layer provided on the lower layer; and
a solder mask provided on the substrate core, the solder mask including a lower portion provided on the substrate core, and an upper portion provided on the lower portion, the lower portion covering a top peripheral region of the lower layer of the bump land, and the upper portion exposing a top face of the upper layer of the bump land.

2. The circuit substrate of claim 1, wherein the lower portion of the solder mask surrounds a side face of the upper layer of the bump land.

3. The circuit substrate of claim 1, wherein the top face of the upper layer of the bump land is positioned higher than a top face of the lower portion of the solder mask.

4. The circuit substrate of claim 1, wherein the upper portion of the solder mask has a window exposing the upper layer of the bump land, and a side face of the window is spaced apart from a side face of the upper layer of the bump land.

5. The circuit substrate of claim 1, wherein the upper layer of the bump land has a circular shape.

6. The circuit substrate of claim 5, wherein the upper portion of the solder mask has a window with a circular shape exposing the upper layer of the bump land, and the diameter of the window is larger than that of the upper layer of the bump land.

7. The circuit substrate of claim 1, wherein the lower layer of the bump land is connected to at least one circuit track covered with the lower portion of the solder mask.

8. A circuit substrate comprising:
a substrate core;
a bump land provided on the substrate core, the bump land including a lower layer provided on the substrate core, at least one intermediate layer provided on the lower layer, and an upper layer provided on the at least one intermediate layer; and
a solder mask provided on the substrate core, the solder mask including a lower portion provided on the substrate core, the lower portion covering a top peripheral region of the lower layer of the bump land and surrounding a side face of the at least one intermediate layer of the bump land, and an upper portion provided on the lower portion and exposing a top face and a side face of the upper layer of the bump land.

9. The circuit substrate of claim 8, wherein a major surface area of the upper layer of the bump land is larger than that of the at least one intermediate layer of the bump land.

10. The circuit substrate of claim 8, wherein a bottom face of the upper layer of the bump land is positioned at the same level as a top face of the lower portion of the solder mask.

11. The circuit substrate of claim 8, wherein the upper portion of the solder mask has a window exposing the upper layer of the bump land, and a side face of the window is spaced apart from a side face of the upper layer of the bump land.

12. The circuit substrate of claim 8, wherein the upper layer of the bump land has a circular shape.

13. The circuit substrate of claim 12, wherein the upper portion of the solder mask has a window with a circular shape exposing the upper layer of the bump land, and the diameter of the window is larger than that of the upper layer of the bump land.

14. The circuit substrate of claim 8, wherein the lower layer of the bump land is connected to at least one circuit track covered with the lower portion of the solder mask.

15. A bump land structure comprising:
a bump land including
a lower layer having a major surface with a mounting region and a peripheral region contiguous with and surrounding the mounting region, and
an upper layer provided on the mounting region of the major surface of the lower layer; and
a solder mask covering the entire peripheral region of the major surface of the lower layer of the bump land.

16. The bump land structure of claim 15, wherein the solder mask contacts a side surface of the upper layer of the bump land.

17. The bump land structure of claim 15, wherein the bump land further includes at least one intermediate layer interposed between the lower layer and the upper layer.

18. The bump land structure of claim 17, wherein the solder mask contacts a side surface of the at least one intermediate layer of the bump land.

19. The bump land structure of claim 15, wherein solder mask includes a lower portion covering the entire peripheral region of the major surface of the lower layer of the bump land, and an upper portion provided on the lower portion.

20. A circuit substrate provided with a bump land structure according to claim 15.

21. A method of manufacturing a bump land structure, the method comprising:
providing a bump land lower layer having a major surface with a mounting region and a peripheral region contiguous with and surrounding the mounting region;
providing a bump land upper layer on the mounting region of the major surface of the bump land lower layer; and
providing a solder mask covering the entire peripheral region of the major surface of the bump land lower layer.

22. A bump land structure manufactured in accordance with the method of claim 21.
